(19) United States
(12) Patent Application Publication
(10) Pub. No.: US 2017/0365816 A1
(43) Pub. Date: Dec. 21, 2017

(54) SELF-LUMINOUS APPARATUS, METHOD OF MANUFACTURING THEREOF AND DISPLAY APPARATUS

(71) Applicant: Shenzhen China Star Optoelectronics Technology Co., Ltd., Shenzhen (CN)

(72) Inventor: Chao HE, Shenzhen (CN)

(73) Assignee: Shenzhen China Star Optoelectronics Technology Co., Ltd., Shenzhen (CN)

(21) Appl. No.: 15/289,337

(22) Filed: Oct. 10, 2016

(30) Foreign Application Priority Data
Jun. 17, 2016 (CN) 2016104379340

(51) Int. Cl. H01L 51/52; H01L 27/32

(52) U.S. Cl. CPC H01L 51/5275; H01L 27/32

(57) ABSTRACT

The present application discloses a self-luminous apparatus including: a first electrode layer, a second electrode layer, a light emitting layer between the first electrode layer and the second electrode layer, and an insulating layer between or outside the first electrode layer and the first substrate; wherein, at least one layer of the insulating layer, the first electrode layer and the second electrode layer is produced a hybrid structure having mixed material with high and low refractive index by the changes of the temperature and/or pressure and chemical vapor deposition to improve light emission efficiency. The present application also discloses a method to manufacturing the self-luminous apparatus and a display apparatus. By the way mentioned above, making the light pass the hybrid structure having mixed material with high and low refractive index to scattering or refraction light, reducing the total reflection of light and improve the light transmittance of the apparatus.

### FIELD OF THE INVENTION

The present application relates to an organic light emitting technology field, and more particularly to a self-luminous apparatus, method of manufacturing thereof and display apparatus.

### BACKGROUND OF THE INVENTION

The Organic Light-Emitting Diode, OLED display has become a new generation of display technology, because it can self-luminous, no need of backlight, but also has features of simple structure, ultra-thin, fast response, wide viewing angle, low power consumption and can realize the flexible display device, coupled with its production equipment investment is far smaller than the liquid crystal display, LCD, it has become the main force of the third generation display of display devices in the display technology field.

Although the organic light-emitting diodes have many advantages, but it also has its own deficiencies, low photon utilization rate is one of that. The light emitting from the light emitting layer inside the organic light emitting diode is affected by the factors of indium tin oxide (ITO), glass substrate, the internal different functional layers of the organic light emitting structure, the reflection and refraction of the glass substrate and the air surface layer and others, about 80% photon cannot escape into the air, thus the photon utilization rate is low. In order to improve light extraction efficiency of the device, researchers have proposed a number of methods, such as by changing the structure of the electrodes of the device, inserting a light extraction layer inside the OLED, or etching various micro structures in the surface of the substrate. These methods can improve the light extraction efficiency of the OLED in a level, but the process is complex, difficult to achieve in practice, and changing the internal structure or etching are easily to affect the performance of the OLED itself.

### SUMMARY OF THE INVENTION

The main technology problem solved in the present application is to provide a self-luminous apparatus, a method of manufacturing thereof and a display apparatus to solve the low light extraction efficiency of the OLED and the conventional complicated process to improve the issue.

In order to solve the technology problem above, the technology approach adapted in the present application is providing a method of manufacturing a self-luminous apparatus, including:

forming a first electrode layer, a second electrode layer, a first substrate outside the first electrode layer, a light emitting layer between the first electrode layer and the second electrode layer, and an insulating layer between or outside the first electrode layer and the first substrate;

wherein, when forming at least one layer of the insulating layer and the first electrode layer, by the changes of the temperature and/or pressure and chemical vapor deposition to form a hybrid structure having mixed material with high and low refractive index to improve light emission efficiency; and

the hybrid structure having mixed material with high and low refractive index is the structure of particles with relatively low refractive index distributed in the relatively high refractive index layer.

wherein by the changes of the temperature and/or pressure and chemical vapor deposition to form a hybrid structure having mixed material with high and low refractive index including cooling down or decompression the fluid or liquid solution containing a plurality of particles with relatively low solid solubility to form a solid with a plurality of induced microporous.

wherein the size and/or the refractive index, and the density of the particles are not the same.

In order to solve the technology problem above, the technology approach adapted in the present application is providing a self-luminous apparatus, including:

a first electrode layer, a second electrode layer, a light emitting layer between the first electrode layer and the second electrode layer, and an insulating layer between or outside the first electrode layer and the first substrate;

wherein, at least one layer of the insulating layer, the first electrode layer and the second electrode layer is produced a hybrid structure having mixed material with high and low refractive index by the changes of the temperature and/or pressure and chemical vapor deposition to improve light emission efficiency.

wherein the hybrid structure having mixed material with high and low refractive index is the structure of particles with relatively low refractive index distributed in the relatively high refractive index layer.

wherein the hybrid structure having mixed material with high and low refractive index formed by the changes of the temperature and/or pressure and chemical vapor deposition including cooling down or decompression the fluid or liquid solution containing a plurality of particles with relatively low solid solubility to form a solid with a plurality of induced microporous.

wherein the size and/or the refractive index, and the density of the particles are not the same.

Wherein further including: a first substrate formed outside the first electrode layer, the light emitting surface of the self-luminous apparatus is the side of the light emitting layer facing away the first substrate, the layer of the hybrid structure having mixed material with high and low refractive index is disposed between the first substrate and the first electrode layer.

Wherein further including: a first substrate formed outside the first electrode layer, a second substrate formed outside the second electrode layer, the light emitting surface of the self-luminous apparatus is in a side of the second substrate, the layer of the hybrid structure having mixed material with high and low refractive index is disposed between the second substrate and the second electrode layer.

Wherein further including: a first substrate formed outside the first electrode layer, a second substrate formed outside the second electrode layer, the light emitting surface of the self-luminous apparatus is in a side of the second substrate, the quantity of the layer of the hybrid structure having mixed material with high and low refractive index is two, one of the layer is disposed between the second substrate and the second electrode layer, the other layer is disposed outside the second substrate.

Wherein further including: a first substrate formed outside the first electrode layer, a second substrate formed outside the second electrode layer, the light emitting surface of the self-luminous apparatus is in a side of the second substrate, the quantity of the layer of the hybrid structure having mixed material with high and low refractive index is two, one of the layer is disposed between the first substrate and the first electrode layer, the other layer is disposed between the second substrate and the second electrode layer.

In order to solve the technology problem above, the technology approach adapted in the present application is providing a display apparatus, including:

a display panel and a driving circuit connected to the display panel;

the display panel is a self-luminous apparatus having a plurality of pixel unit, the self-luminous apparatus including:

a first electrode layer, a second electrode layer, a light emitting layer between the first electrode layer and the second electrode layer, and an insulating layer between or outside the first electrode layer and the first substrate;

wherein, at least one layer of the insulating layer, the first electrode layer and the second electrode layer is produced a hybrid structure having mixed material with high and low refractive index by the changes of the temperature and/or pressure and chemical vapor deposition to improve light emission efficiency.

wherein the hybrid structure having mixed material with high and low refractive index is the structure of particles with relatively low refractive index distributed in the relatively high refractive index layer.

wherein the hybrid structure having mixed material with high and low refractive index formed by the changes of the temperature and/or pressure and chemical vapor deposition including cooling down or decompression the fluid or liquid solution containing a plurality of particles with relatively low solid solubility to form a solid with a plurality of induced microporous.

wherein the size and/or the refractive index, and the density of the particles are not the same.

Wherein further including: a first substrate formed outside the first electrode layer, the light emitting surface of the self-luminous apparatus is the side of the light emitting layer facing away the first substrate, the layer of the hybrid structure having mixed material with high and low refractive index is disposed between the first substrate and the first electrode layer.

Wherein further including: a first substrate formed outside the first electrode layer, a second substrate formed outside the second electrode layer, the light emitting surface of the self-luminous apparatus is in a side of the second substrate, the layer of the hybrid structure having mixed material with high and low refractive index is disposed between the second substrate and the second electrode layer.

Wherein further including: a first substrate formed outside the first electrode layer, a second substrate formed outside the second electrode layer, the light emitting surface of the self-luminous apparatus is in a side of the second substrate, the quantity of the layer of the hybrid structure having mixed material with high and low refractive index is two, one of the layer is disposed between the second substrate and the second electrode layer, the other layer is disposed outside the second substrate.

Wherein further including: a first substrate formed outside the first electrode layer, a second substrate formed outside the second electrode layer, the light emitting surface of the self-luminous apparatus is in a side of the second substrate, the quantity of the layer of the hybrid structure having mixed material with high and low refractive index is two, one of the layer is disposed between the first substrate and the first electrode layer, the other layer is disposed between the second substrate and the second electrode layer.

The advantage of the present application is: comparing to the conventional technology, the present application provides a self-luminous apparatus including: a first electrode layer, a second electrode layer, a light emitting layer between the first electrode layer and the second electrode layer, and an insulating layer between or outside the first electrode layer and the first substrate; wherein at least one layer of the insulating layer, the first electrode layer and the second electrode layer is produced a hybrid structure having mixed material with high and low refractive index by the changes of the temperature and/or pressure and chemical vapor deposition to improve light emission efficiency. By the way mentioned above, when forming at least one layer of the insulating layer, the first electrode layer and the second electrode layer, forming the hybrid structure having mixed material with high and low refractive index by the changes of the temperature and/or pressure and chemical vapor deposition, makes the light emitting from the light emitting layer pass the hybrid structure having mixed material with high and low refractive index to scattering or refraction light, reducing the total reflection of light in the interface and improve the light transmittance, thereby increase the light extraction efficiency of the self-luminous apparatus. By the production mode of changing of the temperature and/or pressure and chemical vapor deposition in the present application, the manufacturing cost is low and is suitable for mass production.

### BRIEF DESCRIPTION OF THE DRAWINGS

In order to more clearly illustrate the embodiments of the present application or prior art, the following figures will be described in the embodiments are briefly introduced. It is obvious that the drawings are merely some embodiments of the present application, those of ordinary skill in this field can obtain other figures according to these figures without paying the premise.

FIG. 1 illustrates a schematic structure of a self-luminous apparatus of the first embodiment in the present application;

FIG. 2 illustrates a schematic structure of a self-luminous apparatus of the second embodiment in the present application;

FIG. 3 illustrates a schematic structure of a self-luminous apparatus of the third embodiment in the present application;

FIG. 4 illustrates a schematic structure of a self-luminous apparatus of the fourth embodiment in the present application;

FIG. 5 illustrates a schematic structure of a self-luminous apparatus of the fifth embodiment in the present application;

FIG. 6 is a schematic flow diagram of a method of manufacturing the self-luminous apparatus of an embodiment in the present application; and

FIGS. 7a-7e illustrate cross-sectional schematic structures of the self-luminous apparatus in each steps in FIG. 6.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts obtained should be considered within the scope of protection of the present application.

Specifically, the terminologies in the embodiments of the present application are merely for describing the purpose of the certain embodiment, but not to limit the invention. Examples and the claims be implemented in the present application requires the use of the singular form of the book “an”, “the” and “the” are intend to include most forms unless the context clearly dictates otherwise. It should also be understood that the terminology used herein that “and/or” means and includes any or all possible combinations of one or more of the associated listed items.

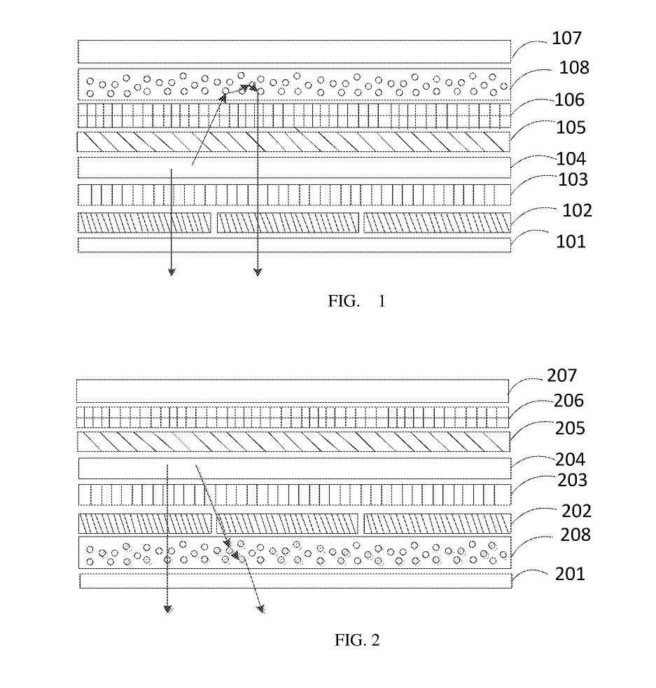

Referring to FIG. 1, a self-luminous apparatus of the first embodiment in the present application, includes a first electrode layer 106, a second electrode layer 102, a light emitting layer 104 disposed between the first electrode layer 106 and the second electrode layer 102, an insulating layer 108 disposed outside the first electrode layer 106 and the second electrode layer 102.

Wherein, at least one layer of the insulating layer 108, the first electrode layer 106 and the second electrode layer 102 is a hybrid structure having mixed material with high and low refractive index 108 formed by the changes of the temperature and/or pressure to improve light emission efficiency.

Specifically, since the self-luminous apparatus is constituted by an anodic and a cathode formed on an insulator, and an organic light emitting material with electroluminescent sandwiched between the anode and the cathode, the layer having organic light emitting material with electroluminescent is referred to as a light emitting layer. The self-luminous apparatus generally includes an OLED, a photovoltaic apparatus, or any other suitable apparatus; the present embodiment is taken OLED as an example for specifically description.

The OLED has the first electrode layer 106, the second electrode layer 102 and the light emitting layer 104 formed as a sandwich structure, the first electrode layer 106 can be selected as a cathode, and using the metal material of aluminum, silver, or indium; or a composite metal with low work function such as the material of magnesium and silver. The second electrode layer 102 can be selected as an anode formed by the material of transparent conductive material or transparent conductive oxide material; the light emitting layer 104 typically includes red, green, and blue three different organic light emitting material forming three sub-pixels to emit color light.

A hole transport layer 103 and electron transport layer 105 are further included between the first electrode layer 106 and the second electrode layer 102. When applying a voltage, the anode hole and the cathode electron are combined in the light emitting layer 104 to emit light and produce bright. A first substrate 107 and a second substrate 101 are added on the first electrode layer 106 and the second electrode layer 102 respectively to play a good role in package, the first substrate 107 and the second substrate 101 is selected as glass substrate.

The light emitted from the light-emitting layer 104 is emission into the air from the light emitting surface, the light emitting surface is usually provided in the second electrode layer 102 side, mainly due to the good transparency of the material of the anode. The light emitted from the light emitting layer 104 is emission in 360 degree. During the transmission of the light, since the refractive index of the light-emitting layer 104 is usually higher than the refractive index of the other layer, the light is transmitted from the high refractive index layer to the lower refractive index layer, most of the light occurring totally reflection and is trapped in the contact surface of the second electrode layer 102 and the second substrate 101, and the contact surface of the second substrate 101 and the air and cannot escape into the air, causing the low photon utilization rate.

Accordingly, in this embodiment, the insulating layer 108 is disposed between or outside the first electrode layer 106 and the second electrode layer 102, at least one layer of the insulating layer, the first electrode layer 106 or the second electrode layer 102 are process by the changes of the temperature and/or pressure, such as annealing process, to form a hybrid structure having mixed material with high and low refractive index 108, the hybrid structure having mixed material with high and low refractive index 108 can refractor scatter the light emitted from the light-emitting layer 104, and change the light transporting direction, reduce light occurring total reflection at the interface, which is extracted the light originally trapped in the apparatus, so that more light can pass through the second electrode layer 102 and the second substrate 101 and transport into the air to increase the light transmittance, thereby effectively improve the light extraction efficiency of the apparatus.

Wherein the hybrid structure having mixed material with high and low refractive index 108 refers to the hybrid structure including at least two material with different refractive index, optionally, the structure can be particles with relatively low refractive index distributed in the relatively high refractive index layer, the particles with relatively low refractive index can be one or more types, the size, refractive index, and density of the particles are not the same, it can produce good scattering effect to light. In general, the relatively high refractive index layer is solid, the relatively low refractive index particles are gas, or microporous structure after the gas evaporation or precipitation.

The method of manufacturing the hybrid structure having mixed material with high and low refractive index 108 is selected as: by cooling down or decompression the fluid or liquid solution containing a plurality of particles with relatively low solid solubility to form a solid 180 with a plurality of induced microporous. For example, the plurality of particles with relatively low solid solubility is helium ions, the fluid or liquid solution is silicon nitride in liquid type, a layer of silicon nitride thin film is formed by chemical vapor deposition, a certain amount of helium ions is implanted into the silicon nitride by ion implantation. After completing the helium ion implantation, the helium ions are separate out by the annealing process to form the silicon nitride solid 108 with the plurality of induced microporous, this production mode is suitable for mass production, and in low cost.

The thickness of the silicon nitride solid 108 with the plurality of induced microporous is not limited, and can be any suitable thickness to meet the requirements, optionally is 0.5-1.5 μm; the diameter of the microporous is not restricted, can be any suitable size to meet the requirements, optionally is 1-10 nm.

The microporous with different pore size and distribution number can be formed by changing the densification degree of the silicon nitride, the concentration of the implantation of the helium ion, the annealing time/temperature and other formation conditions. The shape of the microporous can be, but is not limited to spherical, cylindrical or slit-like type, the microporous can be connected or disconnected between others, the plurality of the microporous can be randomly distributed or arranged according to certain rules in the silicon nitride solids.

Further, other inert gas ions can also be implanted in the silicon nitride, or several different inert gas ions can be implanted simultaneously to form the microporous with different sizes and shapes.

When light enters the silicon nitride solid, the light is repeatedly scattering by the inside induced microporous, to reduce total reflection occurs at the interface of the light, so more light is emitting from the apparatus into the air, increasing the light transmittance, effectively improve light extraction efficiency.

In the present embodiment, the hybrid structure having mixed material with high and low refractive index 108 is defined as the insulating layer 108, the insulating layer 108 is an Individual layer, it can be disposed between the first substrate 107 and the first electrode layer 106, as shown in FIG. 1, and it can disposed between the other layers and the substrates, which is described in the following embodiments.

In other embodiments, the insulating layer can also be directly selected as the first substrate or the second substrate, in the premise without affecting the basic functions of the first substrate or the second substrate to form the substrate with the high and low refractive index material hybrid structure, such that light pass through the first substrate and the second substrate occurring scattering or refraction, and reducing the occurrence of total reflection of light.

Alternatively, a bilayer structure containing the hybrid structure having mixed material with high and low refractive index is formed on the first electrode layer or the second electrode layer, wherein one layer achieve the basic functions of the first electrode layer or the second electrode layer, another layer forming the hybrid structure having mixed material with high and low refractive index, such that light pass through the first substrate and the second substrate occurring scattering or refraction, and reducing the occurrence of total reflection of light.

Alternatively, the first electrode layer or the second electrode layer are directly formed to be the hybrid structure having mixed material with high and low refractive index, the first electrode layer or the second electrode layer with the hybrid structure having mixed material with high and low refractive index can achieve the itself substrate function and can also achieve the function to scattering or refraction the light and reducing the occurrence of total reflection of light.

Referring to FIG. 2, the self-luminous apparatus of the second embodiment in the present application, take OLED as an example, includes a first electrode layer 206, a second electrode layer 202, a light-emitting layer 204 disposed between the first electrode layer 206 and the second electrode layer 202, an electron transport layer 205 disposed between the first electrode layer 206 and the light-emitting layer 204, a hole transport layer 203 disposed between the second electrode layer 202 and the light-emitting layer 204, the insulating layer 208 disposed between the second electrode layer 202 and the second substrate 201, a first substrate 207 is disposed outside the first electrode layer 206, a second substrate 201 is disposed outside the second electrode layer 202.

Wherein the first electrode layer 206 is a cathode, optionally formed by metal aluminum material, the second electrode layer 202 is an anode, optionally formed by ITO material, the first substrate 207 and the second substrate 201 are glass substrate optionally, a silicon nitride solid with a plurality of induced microporous is formed on the insulating layer 208, the induced microporous is formed by implanting helium ions in the silicon nitride thin film, and by the way of performing an annealing process to separate out the helium ions.

The light emitted from the light emitting layer 204 and emission into the air through the second substrate 201, when the light enters the insulating layer 208, are repeatedly scattered by the function of the induced microporous inside, changing the transmission direction of the light, reducing the light occurring totally reflection from the second electrode layer 202 toward the lower surface of the second substrate 201 of the original OLED structure, and the lower surface of the substrate 201 in contact with the air, makes the light transmitting the second electrode, the second substrate 201 and emitting into the air, such that to extract the light originally trapped in the apparatus, and to increase the light transmittance rate and effectively improving the light extraction efficiency.

In the present embodiment, the first substrate 207 can also not be covered above the first electrode layer 206.

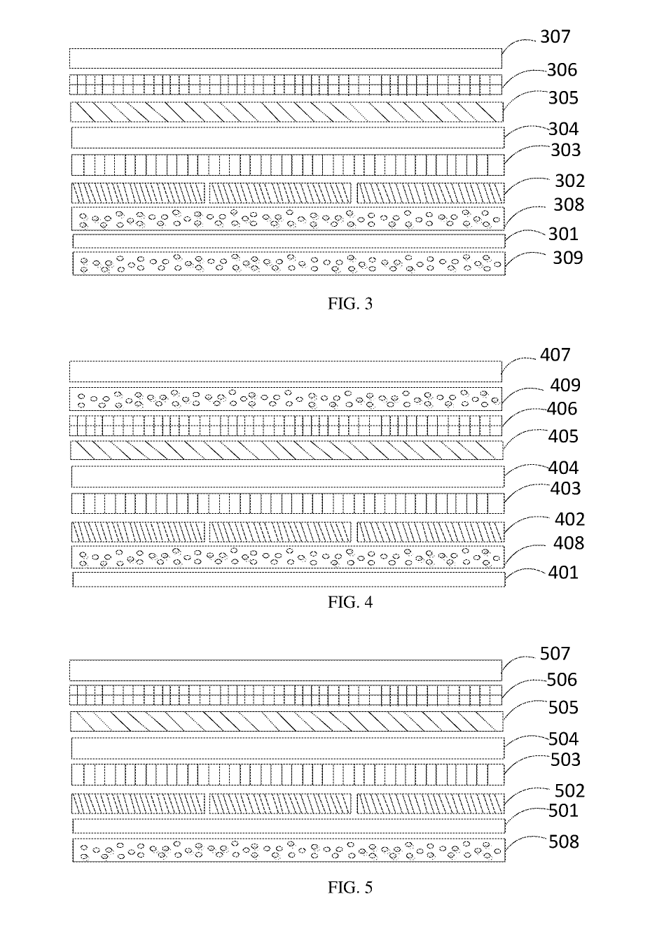

Referring to FIG. 3, FIG. 3 illustrates a schematic structure of a self-luminous apparatus of the third embodiment in the present application. The OLED structure of FIG. 3 is similar to the OLED structure of FIG. 2, and is not detailed description here. The difference is the quantity of insulating layer 308/309 is two, one of the insulating layer 308 is disposed between the second substrate 301 and the second electrode layer 302, the other insulating layer 309 is disposed outside the second substrate 301.

Referring to FIG. 4, FIG. 4 illustrates a schematic structure of a self-luminous apparatus of the fourth embodiment in the present application. The OLED structure of FIG. 4 is similar to the OLED structure of FIG. 2, and is not detailed description here. The difference is the quantity of insulating layer 408/409 is two, one of the insulating layer 409 is disposed between the first substrate 407 and the first electrode layer 406, and the other insulating layer 408 is disposed between the second substrate 401 and the second electrode layer 402.

Referring to FIG. 5, FIG. 5 illustrates a schematic structure of a self-luminous apparatus of the fifth embodiment in the present application. The OLED structure of FIG. 5 is similar to the OLED structure of FIG. 2, and is not detailed description here. The difference is the insulating layer 508 is disposed on the second substrate 501 remote from the outside of the second electrode layer 502.

One embodiment of the display apparatus of the present application is an OLED display apparatus includes a display panel and a driving circuit connected to the display panel, the driving circuit is for driving the pixel unit to emit light, the display region of the display panel is a self-luminous apparatus having a plurality of pixel units, each pixel unit includes a first sub-pixel displaying a first color, a second sub-pixel displaying a second color, and a third sub-pixel displaying a third color, each of the pixel unit can be the self-luminous apparatus in any of the above embodiments.

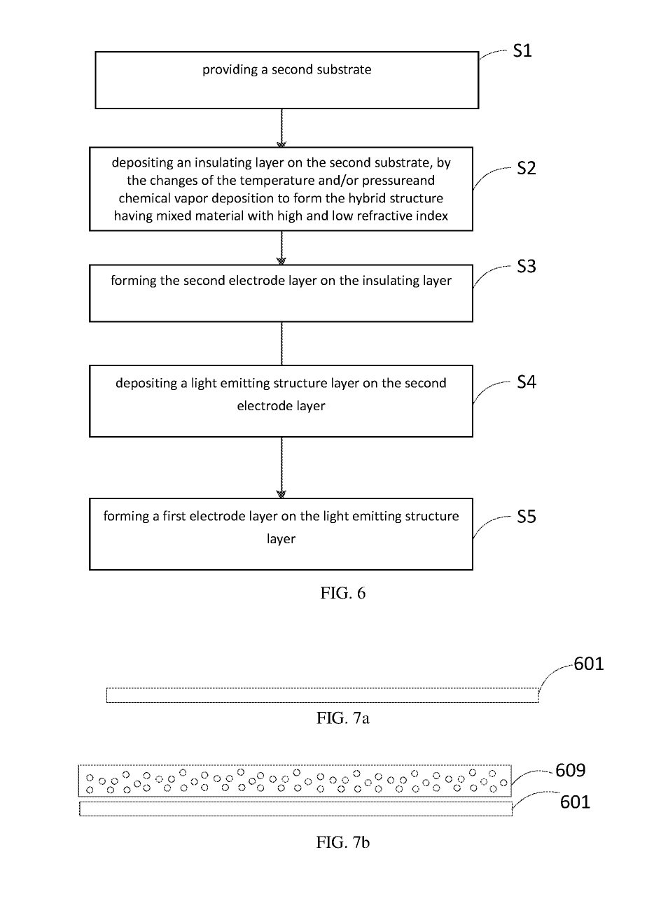

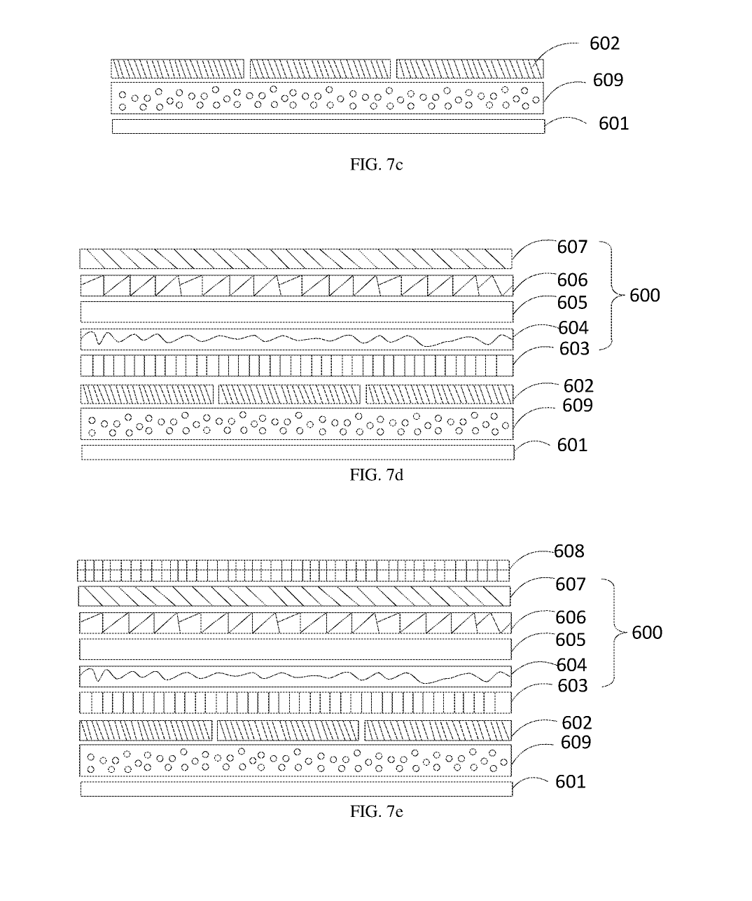

FIG. 6 is a schematic flow diagram of a method of manufacturing the self-luminous apparatus of an embodiment in the present application. FIGS. 7a-7e illustrate cross-sectional schematic structures of the self-luminous apparatus in each steps in FIG. 6. Referring to 6 and 7, the method of manufacturing the self-luminous apparatus includes the following steps:

S1: providing a second substrate 601;

The second substrate 601 can be a rigid substrate, a flexible substrate, not limited to this, referring to FIG. 7a.

S2: depositing an insulating layer 609 on the second substrate 601, by the changes of the temperature and/or pressure to form the hybrid structure having mixed material with high and low refractive index 609;

Specifically, a silicon nitride film is deposited on the second substrate 601 by chemical vapor deposition technology, a certain amount of helium ions is implantation injected to the silicon nitride, after the ion implantation is completed, the helium ions are separate out by the annealing process to form induced microporous, the silicon nitride structure 609 with induced microporous is a hybrid structure having mixed material with high and low refractive index 609, referring to FIG. 7b.

S3: forming the second electrode layer 602 on the insulating layer;

The second electrode layer 602 is an anode, an ITO film is formed by physical vapor deposition techniques, referring to FIG. 7c.

S4: depositing a light emitting structure layer 600 on the second electrode layer 602;

The light emitting structure layer 600 is formed on the second electrode layer 602 by vapor deposition process, specifically, the hole transport layer 603, the hole injection layer 604, the light emitting layer 605, the electron injection layer 606 and the electron transporting layer 607 are deposited by vapor deposition process subsequently. Since the light emitting structure layer belongs to the micro-cavity structure, the specific thickness of each layer structure need to be determined according to the cavity length of the micro-cavity, therefore, this is not specifically defined, referring to FIG. 7d.

S5: forming a first electrode layer 608 on the light emitting structure layer 600;

The first electrode layer 608 is formed on the electron transport layer 607, the first electrode layer 608 can be selected as a cathode, adapting the metal material of the aluminum, silver or indium, and a complex metal having low work function such as magnesium silver material.

It need to be noted that, before or after the step S2 mentioned above, a thin film transistor array substrate, i.e. a TFT array can be formed on the second substrate 601. Wherein, the TFT array including: a semiconductor layer, a gate electrode, a gate insulating layer, a source electrode, a drain electrode, a passivation layer and the like structure, the structures above are sequentially formed in accordance with the conventional technology of process technology of the film layer structure (deposition, photolithography process) to form a top-gate structure, or a bottom gate structure. The TFT array can be used to adjust and driving the self-luminous apparatus.

As it can be seen, when forming the insulating layer 609 in the present embodiment, the silicon nitride 609 with plurality of the induced microporous structure is formed by ion implantation, and the annealing process. It makes the light emitted from the light emitting layer 605 and passed the insulating layer 609, are repeatedly scattered by the function of the induced microporous inside, changing the transmission direction of the light, reducing the light occurring totally reflection from the interface of the second electrode layer and the second substrate, and the interface of the second substrate and the air, to extract the light, and increase the light extraction efficiency of the apparatus. Moreover, the mode of production to produce the silicon nitride structure having a plurality of microporous structure is not complicated, lower cost, suitable for mass production.

In other embodiments, in the process of forming the first electrode layer or the second electrode layer, it can also produce the hybrid structure having mixed material with high and low refractive index, such that under the premise of basic functions of the first electrode layer or the second electrode layer, while the use of this hybrid structure having mixed material with high and low refractive index to scattering or refraction light, reducing the total reflection of light and improve the light transmittance of the apparatus.

Above are embodiments of the present application, which does not limit the scope of the present application. Any modifications, equivalent replacements or improvements within the spirit and principles of the embodiment described above should be covered by the protected scope of the invention.

What is claimed is:

1. A method of manufacturing a self-luminous apparatus, comprising:
forming a first electrode layer, a second electrode layer, a first substrate outside the first electrode layer, a light emitting layer between the first electrode layer and the second electrode layer, and an insulating layer between the first electrode layer and the first substrate;
wherein, when forming at least one layer of the insulating layer and the first electrode layer, by the changes of the temperature and/or pressure and chemical vapor deposition to form a hybrid structure having mixed material with high and low refractive index to improve light emission efficiency; and
the hybrid structure having mixed material with high and low refractive index is the structure of particles with relatively low refractive index distributed in the relatively high refractive index layer.

2. The method according to claim 1, wherein by the changes of the temperature and/or pressure and chemical vapor deposition to form a hybrid structure having mixed material with high and low refractive index comprising cooling down or decompression the fluid or liquid solution containing a plurality of particles with relatively low solid solubility to form a solid with a plurality of induced microporous.

3. The method according to claim 1, wherein the size and/or the refractive index, and the density of the particles are not the same.

4. A self-luminous apparatus, comprising:
a first electrode layer, a second electrode layer, a light emitting layer between the first electrode layer and the second electrode layer, and an insulating layer between or outside the first electrode layer and the first substrate;
wherein, at least one layer of the insulating layer, the first electrode layer and the second electrode layer is produced a hybrid structure having mixed material with high and low refractive index by the changes of the temperature and/or pressure and chemical vapor deposition to improve light emission efficiency.

5. The self-luminous apparatus according to claim 4, wherein the hybrid structure having mixed material with high and low refractive index is the structure of particles with relatively low refractive index distributed in the relatively high refractive index layer.

6. The self-luminous apparatus according to claim 5, wherein the hybrid structure having mixed material with high and low refractive index formed by the changes of the temperature and/or pressure and chemical vapor deposition comprising cooling down or decompression the fluid or liquid solution containing a plurality of particles with relatively low solid solubility to form a solid with a plurality of induced microporous.

7. The self-luminous apparatus according to claim 5, wherein the size and/or the refractive index, and the density of the particles are not the same.

8. The self-luminous apparatus according to claim 4, further comprising:
a first substrate formed outside the first electrode layer, the light emitting surface of the self-luminous apparatus is the side of the light emitting layer facing away the first substrate, the layer of the hybrid structure having mixed material with high and low refractive index is disposed between the first substrate and the first electrode layer.

9. The self-luminous apparatus according to claim 4, further comprising:
a first substrate formed outside the first electrode layer, a second substrate formed outside the second electrode layer, the light emitting surface of the self-luminous apparatus is in a side of the second substrate, the layer of the hybrid structure having mixed material with high and low refractive index is disposed between the second substrate and the second electrode layer.

10. The self-luminous apparatus according to claim 4, further comprising:
a first substrate formed outside the first electrode layer, a second substrate formed outside the second electrode layer, the light emitting surface of the self-luminous apparatus is in a side of the second substrate, the quantity of the layer of the hybrid structure having mixed material with high and low refractive index is two, one of the layer is disposed between the second substrate and the second electrode layer, the other layer is disposed outside the second substrate.

11. The self-luminous apparatus according to claim 4, further comprising:
a first substrate formed outside the first electrode layer, a second substrate formed outside the second electrode layer, the light emitting surface of the self-luminous apparatus is in a side of the second substrate, the quantity of the layer of the hybrid structure having mixed material with high and low refractive index is two, one of the layer is disposed between the first substrate and the first electrode layer, the other layer is disposed between the second substrate and the second electrode layer.

12. A display apparatus, comprising:
a display panel and a driving circuit connected to the display panel;
the display panel is a self-luminous apparatus having a plurality of pixel unit, the self-luminous apparatus comprising:
a first electrode layer, a second electrode layer, a light emitting layer between the first electrode layer and the second electrode layer, and an insulating layer between or outside the first electrode layer and the first substrate;
wherein, at least one layer of the insulating layer, the first electrode layer and the second electrode layer is produced a hybrid structure having mixed material with high and low refractive index by the changes of the temperature and/or pressure and chemical vapor deposition to improve light emission efficiency.

13. The display apparatus according to claim 12, wherein the hybrid structure having mixed material with high and low refractive index is the structure of particles with relatively low refractive index distributed in the relatively high refractive index layer.

14. The display apparatus according to claim 13, wherein the hybrid structure having mixed material with high and low refractive index formed by the changes of the temperature and/or pressure and chemical vapor deposition comprising cooling down or decompression the fluid or liquid solution containing a plurality of particles with relatively low solid solubility to form a solid with a plurality of induced microporous.

15. The display apparatus according to claim 13, wherein the size and/or the refractive index, and the density of the particles are not the same.

16. The display apparatus according to claim 12, further comprising:
a first substrate formed outside the first electrode layer, the light emitting surface of the self-luminous apparatus is the side of the light emitting layer facing away the first substrate, the layer of the hybrid structure having mixed material with high and low refractive index is disposed between the first substrate and the first electrode layer.

17. The display apparatus according to claim 12, further comprising:
a first substrate formed outside the first electrode layer, a second substrate formed outside the second electrode layer, the light emitting surface of the self-luminous apparatus is in a side of the second substrate, the layer of the hybrid structure having mixed material with high and low refractive index is disposed between the second substrate and the second electrode layer.

18. The display apparatus according to claim 12, further comprising:
a first substrate formed outside the first electrode layer, a second substrate formed outside the second electrode layer, the light emitting surface of the self-luminous apparatus is in a side of the second substrate, the quantity of the layer of the hybrid structure having mixed material with high and low refractive index is two, one of the layer is disposed between the second substrate and the second electrode layer, the other layer is disposed outside the second substrate.

19. The display apparatus according to claim 12, further comprising:
a first substrate formed outside the first electrode layer, a second substrate formed outside the second electrode layer, the light emitting surface of the self-luminous apparatus is in a side of the second substrate, the quantity of the layer of the hybrid structure having mixed material with high and low refractive index is two, one of the layer is disposed between the first substrate and the first electrode layer, the other layer is disposed between the second substrate and the second electrode layer.
